(19) United States
(12) Patent Application Publication
(10) Pub. No.: US 2026/0103377 A1
(43) Pub. Date: Apr. 16, 2026

(54) MULTI-CELL PISTON MOTION MEMBRANE MICROELECTROMECHANICAL SYSTEMS (MEMS) APPARATUS AND PROCESS

(71) Applicant: INVENSENSE, INC., San Jose, CA (US)

(72) Inventors: Jotaro Akiyama, Yamanashi (JP); Yuki Shibano, Yamanashi (JP); Daishi Arimatsu, Yamanashi-ken (JP); Kento Kaneko, Yamanashi-Ken (JP)

(21) Appl. No.: 18/913,854

(22) Filed: Oct. 11, 2024

(51) Int. Cl. B81B 7/04; B81C 1/00

(52) U.S. Cl. CPC B81B 7/04; B81C 1/00214; B81B 2201/0264; B81B 2201/0271; B81B 2203/0127; B81B 2203/0307; B81B 2203/04; B81C 2201/0109; B81C 2201/0133

(57) ABSTRACT

Multi-cell piston motion membrane microelectromechanical systems (MEMS) apparatuses and processes are described. Described MEMS sensors or devices can comprise a patterned piston motion membrane array wherein each cell of the patterned piston motion membrane array is connected to at least one other cell of the patterned piston motion membrane array. In addition, MEMS sensors or devices can comprise a patterned transduction membrane array wherein each cell of the patterned transduction membrane array is fixed in position near its periphery relative to a fixed electrode structure via anchor structures or a transduction membrane stiffener. Further design flexibility and improvements are described that provide efficient MEMS sensor die usage, high SNR, and high resonance frequency for described MEMS sensors or devices.

### BACKGROUND

Microelectromechanical systems (MEMS) is a class of structures and/or devices that are fabricated using semiconductor-like processes. MEMS structures and/or devices exhibit mechanical characteristics that include the ability to move or to deform. Examples of MEMS devices include, but are not limited to, gyroscopes, accelerometers, magnetometers, pressure sensors, radio-frequency components, and so on. Silicon wafers that include MEMS structures are referred to as MEMS wafers. Unique challenges exist to provide MEMS devices and/or structures with improved performance and reliability.

For example, MEMS membrane structures are often used as moving members in MEMS devices or sensors to respond to an external input or to create output, where the MEMS membrane structures are anchored at the periphery and free to deflect in response to the input away from anchor, near the center. Deformation of the anchored MEMS membrane structure is limited at anchor, and maximum displacement occur at the MEMS membrane structure center, becoming less toward the anchored areas. Thus, MEMS membrane structure areas close to the anchors do not contribute to MEMS device transducer performance, thereby limiting MEMS device performance for a given MEMS die area.

For instance, as a MEMS capacitive sensor, capacitance change of a MEMS membrane structure becomes smaller resulting in a smaller output signal. In response to this limitation of MEMS membrane structure in capacitive sensors, electrode patterning can be used to account for such differences in displacement in the sensing and non-sensing portions of the MEMS membrane structure to improve signal to noise ratio (SNR). But, despite this potential solution, MEMS die area is still not effectively used.

It is thus desired to provide improved MEMS devices designs and processes that address these and other deficiencies. The above-described deficiencies are merely intended to provide an overview of some of the problems of conventional implementations, and are not intended to be exhaustive. Other problems with conventional implementations and techniques and corresponding benefits of the various aspects described herein may become further apparent upon review of the following description.

### SUMMARY

The following presents a simplified summary of the specification to provide a basic understanding of some aspects of the specification. This summary is not an extensive overview of the specification. It is intended to neither identify key or critical elements of the specification nor delineate any scope particular to any embodiments of the specification, or any scope of the claims. Its sole purpose is to present some concepts of the specification in a simplified form as a prelude to the more detailed description that is presented later.

Multi-cell piston motion membrane microelectromechanical systems (MEMS) apparatuses and processes are described. In a non-limiting example, exemplary MEMS sensors or devices can comprise a patterned piston motion membrane array wherein each cell of the patterned piston motion membrane array is connected to at least one other cell of the patterned piston motion membrane array. In another non-limiting aspect, exemplary MEMS sensors or devices can comprise a patterned transduction membrane array wherein each cell of the patterned transduction membrane array is fixed in position near its periphery relative to a fixed electrode structure via anchor structures or a transduction membrane stiffener. In other non-limiting aspects, design flexibility and improvements are described that provide efficient MEMS sensor die usage, high SNR, and high resonance frequency for described MEMS sensors or devices. In addition, an exemplary fabrication process for the described exemplary MEMS sensors or devices is provided.

These and other embodiments are described in more detail below.

### BRIEF DESCRIPTION OF THE DRAWINGS

Various non-limiting embodiments are further described with reference to the accompanying drawings in which:

FIG. 1 provides a cross-section of exemplary microelectromechanical systems (MEMS) devices or sensors that depicts various non-limiting aspects described herein;

FIG. 2 depicts non-limiting aspects applicable to exemplary MEMS devices or sensors described herein;

FIG. 3 depicts further non-limiting aspects applicable to exemplary MEMS devices or sensors described herein;

FIG. 4 depicts still further non-limiting aspects applicable to exemplary MEMS devices or sensors described herein;

FIG. 5 provides a simplified cross-section of an exemplary MEMS device or sensor that depicts further non-limiting aspects described herein;

FIG. 6 illustrates particular aspects of non-limiting piston motion membrane structure position under deflection or deformation suitable for use in exemplary MEMS devices or sensors described herein;

FIG. 7 provides a top view of an exemplary MEMS device or sensor that depicts further non-limiting aspects described herein;

FIG. 8 depicts still further non-limiting aspects applicable to exemplary MEMS devices or sensors described herein;

FIGS. 9-19 illustrate example, non-limiting, cross-sectional views of exemplary MEMS devices or sensors undergoing fabrication processes in accordance with one or more embodiments described herein; and

FIG. 20 provides yet another cross-section of an exemplary MEMS device or sensor that depicts further non-limiting aspects described herein;

FIG. 21 provides a top view of an exemplary MEMS device or sensor that depicts further non-limiting aspects described herein;

FIG. 22 depicts further non-limiting aspects of exemplary MEMS devices or sensors described herein;

FIG. 23 provides a top view of another exemplary MEMS device or sensor that depicts further non-limiting aspects described herein; and

FIG. 24 provides a non-limiting flow diagram of exemplary methods according to various non-limiting aspects as described herein.

### DETAILED DESCRIPTION

### Overview

While a brief overview is provided, certain aspects of the subject disclosure are described or depicted herein for the purposes of illustration and not limitation. Thus, variations of the disclosed embodiments as suggested by the disclosed apparatuses, systems, and methodologies are intended to be encompassed within the scope of the subject matter disclosed herein.

As described above, MEMS membrane structures are often used as moving members in MEMS devices or sensors to respond to an external input or to create output, where the MEMS membrane structures are anchored at the periphery and free to deflect in response to the input away from anchor, near the center. Deformation of the anchored MEMS membrane structure is limited at anchor, and maximum displacement occur at the MEMS membrane structure center, becoming less toward the anchored areas. Thus, MEMS membrane structure areas close to the anchors do not contribute to MEMS device transducer performance, thereby limiting MEMS device performance for a given MEMS die area.

For instance, as a MEMS capacitive sensor, capacitance change of a MEMS membrane structure becomes smaller resulting in a smaller output signal. In response to this limitation of MEMS membrane structure in capacitive sensors, electrode patterning can be used to account for such differences in displacement in the sensing and non-sensing portions of the MEMS membrane structure to improve SNR. But, despite this potential solution, MEMS die area is still not effectively used. As further described below, other potential solutions to these issues further fail to adequately address these failures to provide MEMS devices employing MEMS membrane structures that efficiently use the MEMS die area, while providing improvements in SNR without suffering from low resonance frequency.

To these and/or related ends, various aspects of MEMS sensors, devices, systems, and methods therefor are described. Various embodiments of the subject disclosure are described herein for purposes of illustration, and not limitation. For example, embodiments of the subject disclosure are described herein in the context of a MEMS sensor, such as a MEMS pressure sensor. However, it can be appreciated that various aspects of the subject disclosure is not so limited. As further detailed below, various exemplary implementations may find application in other areas of MEMS sensor design and/or packaging, without departing from the subject matter described herein.

### Exemplary Embodiments

One or more embodiments are now described more fully hereinafter with reference to the accompanying drawings in which example embodiments are shown. In the following description, for purposes of explanation, numerous specific details are set forth in order to provide a thorough understanding of the various embodiments.

Various references are made herein to compositional features of the disclosed MEMS devices or sensors. resulting from various semiconductor-like processes and materials used in exemplary MEMS fabrication processes. It can be understood that there may be suitable substitutions or alternative materials and/or processes to accomplish the described techniques, devices, processes, and so on. As such, descriptions herein of the various semiconductor-like processes and materials used in exemplary MEMS fabrication processes is intended to provide understanding of the appended claims without limitation.

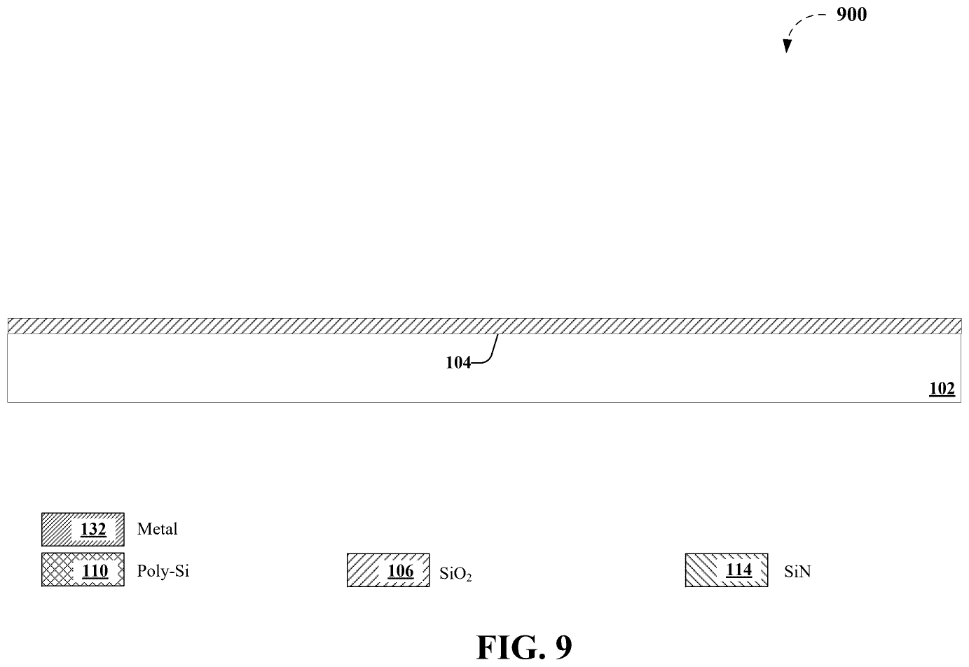

For example, silicon dioxide (SiO₂) can be deposited via an exemplary MEMS fabrication process comprising one or more plasma-enhanced chemical vapor deposition processes (PECVD) employing tetraethylorthosilicate (TEOS) resulting in layers/structures that are derived from such processes including any lithographic patterning and/or etch processes, as further described herein regarding FIGS. 9-19. In another non-limiting example, SiO2 can be deposited via an exemplary MEMS fabrication process comprising one or more low pressure chemical vapor deposition processes (LPCVD) TEOS processes (LPCVD) resulting in layers/structures that are derived from such processes including any lithographic patterning and/or etch processes.

In addition, silicon nitride (SiN) can be deposited via an exemplary MEMS fabrication process comprising one or more LPCVD Low Stress Silicon Nitride (LSN) deposition processes resulting in layers/structures that are derived from such processes including any lithographic patterning and/or etch processes, as further described herein regarding FIGS. 9-19. In another non-limiting example, SiN can be deposited via an exemplary MEMS fabrication process comprising one or more PECVD LSN deposition processes resulting in layers/structures that are derived from such processes including any lithographic patterning and/or etch processes.

As another example, polycrystalline silicon (poly-Si) can be deposited via an exemplary MEMS fabrication process comprising one or more in-situ phosphorous doped polycrystalline silicon deposition processes resulting in layers/structures that are derived from such processes including any lithographic patterning and/or etch processes, as further described herein regarding FIGS. 9-19.

Furthermore, metal alloy such as aluminum-copper (AlCu), chromium-gold (CrAu) can be deposited via an exemplary MEMS fabrication process comprising one or more metal deposition processes resulting in layers/structures that are derived from such processes including any lithographic patterning and/or etch processes.

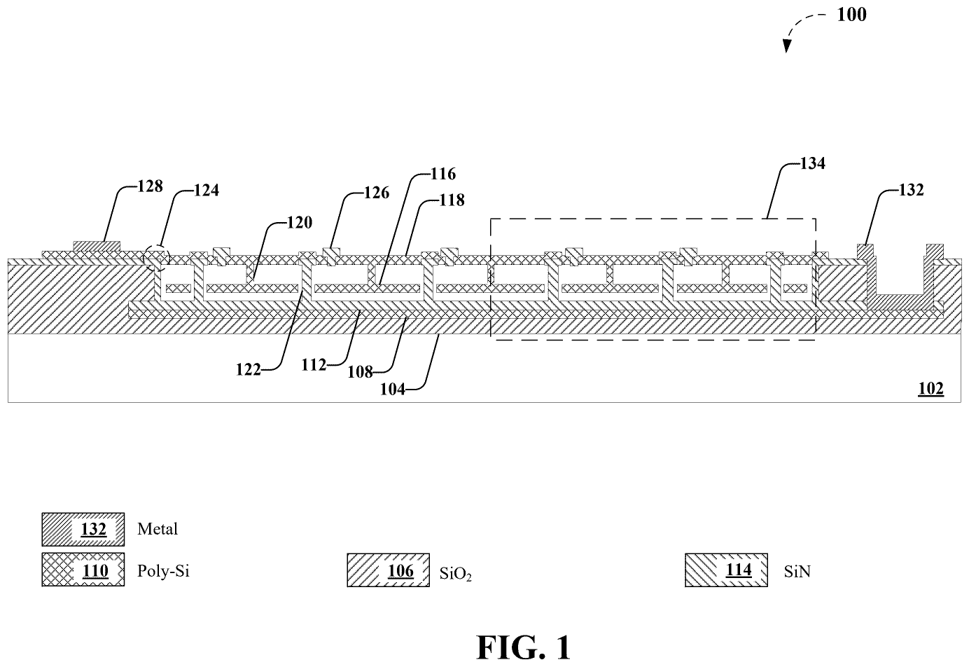

FIG. 1 provides a cross-section of exemplary MEMS devices or sensors 100 that depicts various non-limiting aspects described herein. Exemplary MEMS devices or sensors 100 can comprise a device substrate 102 (e.g., a wafer substrate). In a non-limiting aspect, the device substrate 102 can comprise a silicon wafer, for example. In addition, exemplary MEMS devices or sensors 100 can comprise a device insulating layer 104. For instance, exemplary MEMS devices or sensors 100 can comprise a device insulating layer 104 that can comprise a layer of deposited and/or patterned SiO₂ 106, as further described herein.

In further non-limiting embodiments, exemplary MEMS devices or sensors 100 can further comprise a fixed electrode structure 108. In a non-limiting aspect, exemplary fixed electrode structure 108 can comprise a layer of deposited and/or patterned poly-Si 110, for example, as further described herein. In further non-limiting embodiments, exemplary MEMS devices or sensors 100 can further comprise a passivation layer 112 deposited on top of the fixed electrode structure 108. As a non-limiting example, exemplary passivation layer 112 can comprise a layer of deposited and/or patterned SiN 114, for example, as further described herein.

In still further non-limiting embodiments, exemplary MEMS devices or sensors 100 can further comprise exemplary MEMS device or sensor 100, which can be patterned in an array of piston motion membrane 116 structures. In a non-limiting aspect, a patterned piston motion membrane 116 array can comprise a layer of deposited and/or patterned poly-Si 110, for example, as further described herein.

In yet other non-limiting embodiments, exemplary MEMS devices or sensors 100 can further comprise a transduction membrane 118, which can be patterned in an array of transduction membrane 118 structures, and which cells of the patterned transduction membrane 118 array can be mechanically and electrically coupled to the patterned piston motion membrane 116 array via an array of posts 120 disposed between the transduction membrane 118 and the patterned piston motion membrane 116. In a non-limiting aspect, exemplary transduction membrane 118 and the array of posts 120 can comprise one or more depositions of poly-Si 110, for example, as further described herein.

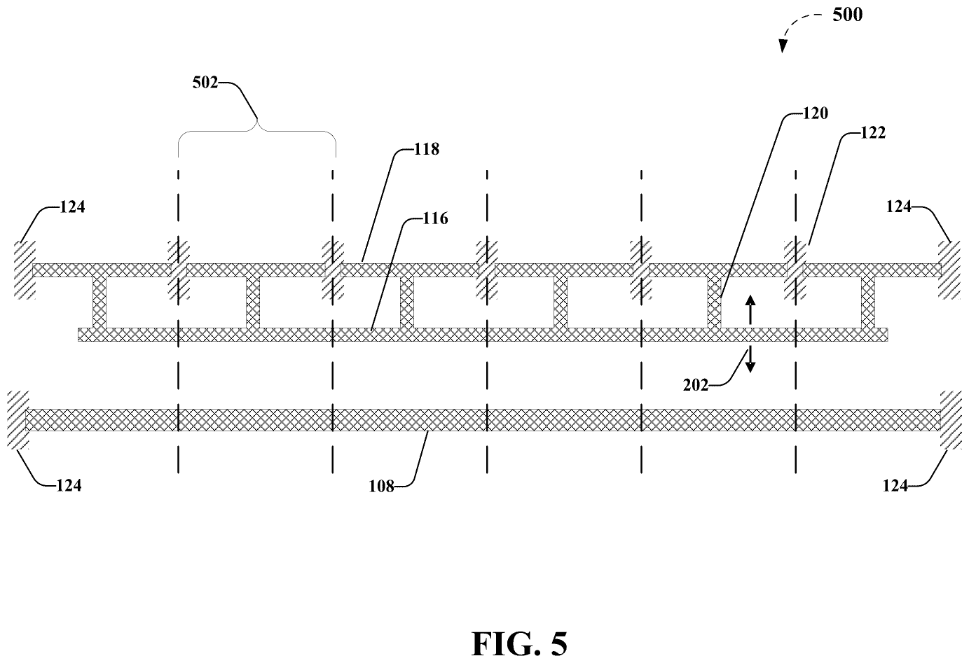

It can be understood that the cells of the exemplary patterned piston motion membrane 116 array and patterned transduction membrane 118 array are shown in a cross-section, which limits the depiction of the characteristics of the respective cells. As further described herein, the number, positioning, configuration (shape and/or construction), and arrangement (relative to other components) of the exemplary patterned piston motion membrane 116 array and patterned transduction membrane 118 array can vary, without limitation, for example, as further described herein regarding FIGS. 5-8 and 20-23.

In further non-limiting embodiments, exemplary MEMS devices or sensors 100 can further comprise a set of anchor structures 122 arranged in an array and deposited on top of the passivation layer 112. As a non-limiting example, exemplary anchor structures 122 can comprise one or more layers of deposited and/or patterned SiN 114, for example, as further described herein. Together with the SiN 114 portions 124 of the MEMS devices or sensors 100 at the periphery of the transduction membrane 118, the set of anchor structures 122 define cells of the patterned transduction membrane 118 array, to which respective cells of the patterned piston motion membrane 116 array are connected via respective posts 120 of the array of posts 120.

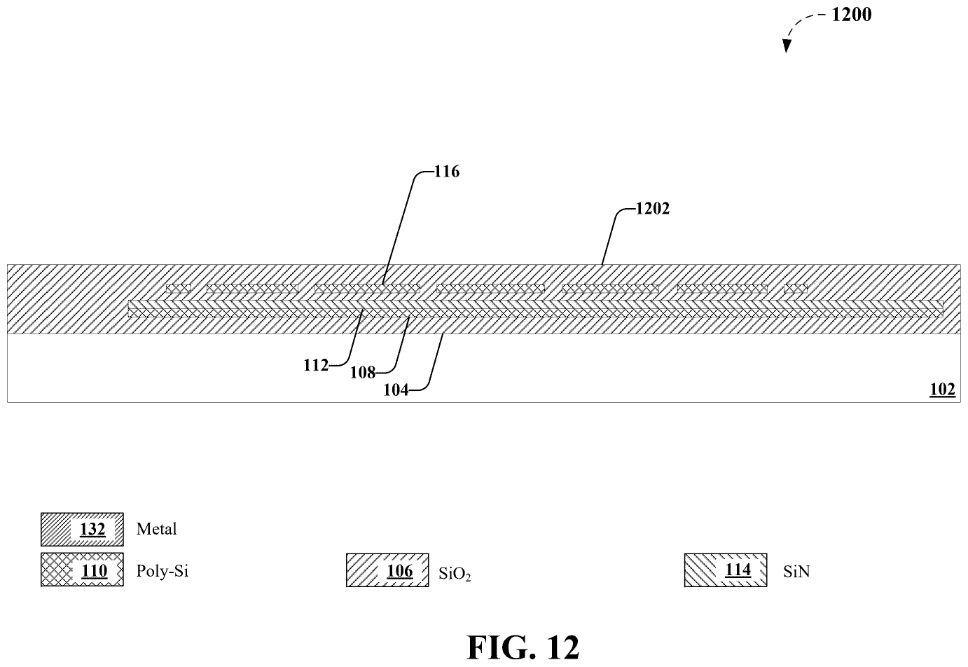

In addition, exemplary MEMS devices or sensors 100 can comprise a set of etch release hole sealing structures 126, which can comprise one or more layers of deposited and/or patterned SiN 114, for example, as further described herein. For example, as further described herein regarding FIGS. 12-17, a set of etch release structures can be configured to enable a uniform wet etch in an area or cavity of the exemplary MEMS devices or sensors 100 between the transduction membrane 118 and the piston motion membrane 116 and freeing the piston motion membrane 116 from the set of anchor structures 122 thus allowing piston motion of the piston motion membrane 116 free of the set of anchor structures 122. As a non-limiting example, the set of etch release structures can comprise a set of passages through the transduction membrane 118 that are configured to allow the wet etch into the area or cavity. In further non-limiting aspects of exemplary MEMS devices or sensors 100, the set of passages through the transduction membrane 118 can be configured to reduce etch time required to equalize an etch in the area or cavity. In still further non-limiting aspects of exemplary MEMS devices or sensors 100, the number, position, and arrangement of the set of passages of the set of etch release structures in the transduction membrane 118 can vary, without limitation, as further described herein.

Exemplary MEMS devices or sensors 100 can further comprise a set of electrical contacts, such as transduction membrane 118 contact pad 128 and fixed electrode structure 108 contact pad 130. As a non-limiting example, exemplary transduction membrane 118 contact pad 128 and fixed electrode structure 108 contact pad 130 can comprise one or more layers of deposited and/or patterned metal 132, for example, as further described herein. It can be understood that, while the various embodiments described herein depict one transduction membrane 118 contact pad 128 and one fixed electrode structure 108 contact pad 130, disclosed subject matter is not so limited. For instance, transduction membrane 118 contact pad 128 and/or fixed electrode structure 108 contact pad 130 can comprise any number of contacts suitable to the MEMS devices or sensors 100 design requirements.

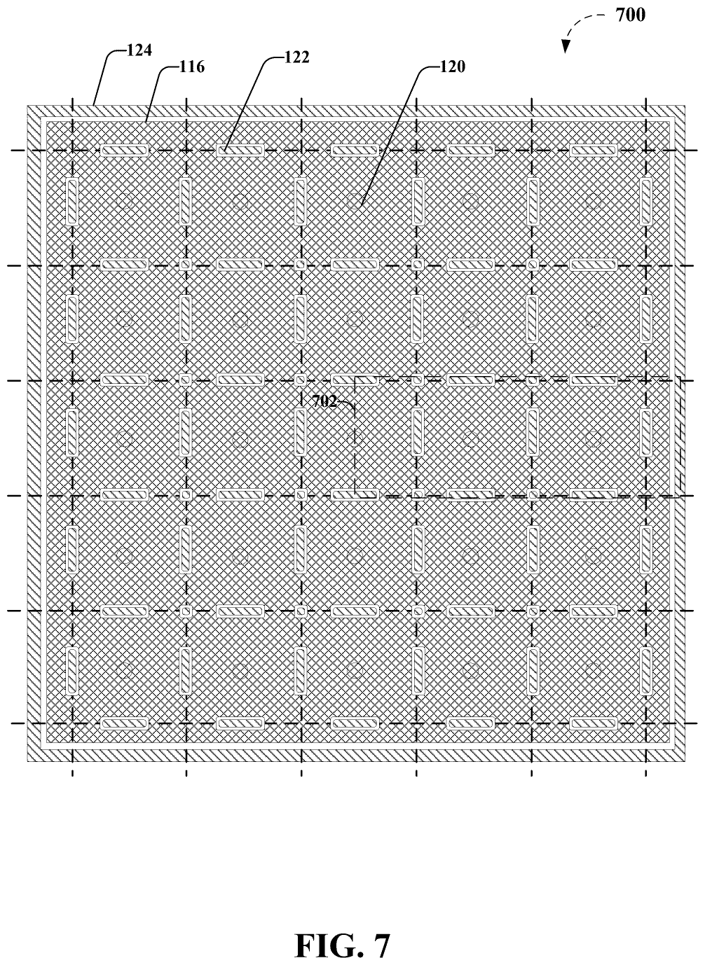

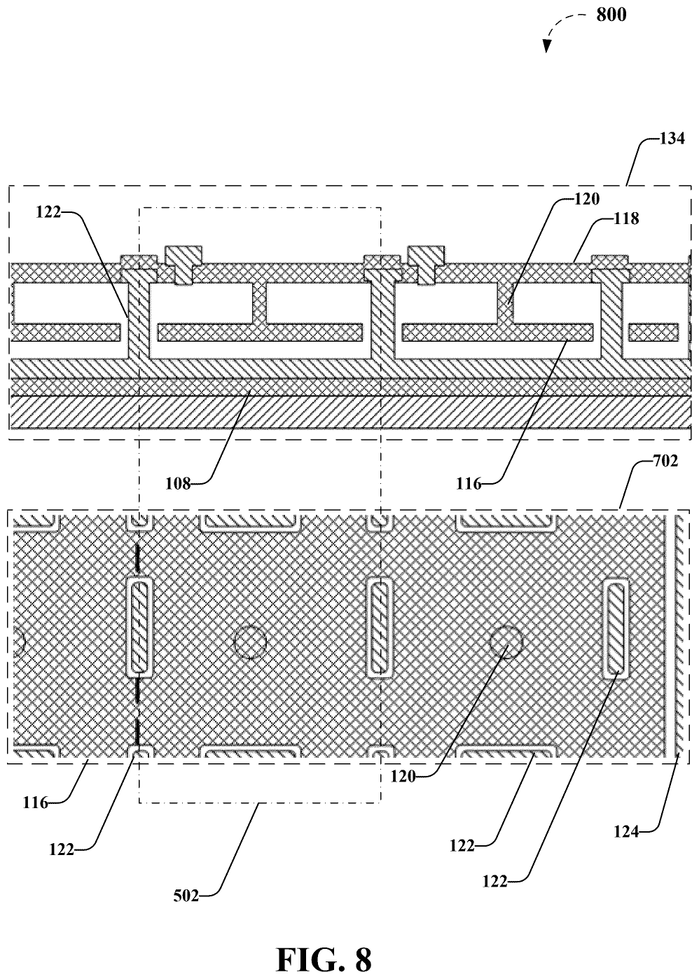

In addition, FIG. 1 depicts inset 134, which, in conjunction with inset 702 in FIGS. 7-8, further illustrates non-limiting aspects of the MEMS devices or sensors 100 regarding anchor structures 122, the patterned piston motion membrane 116 array, and the arrangement of the respective cells of patterned piston motion membrane 116 array in a square pattern.

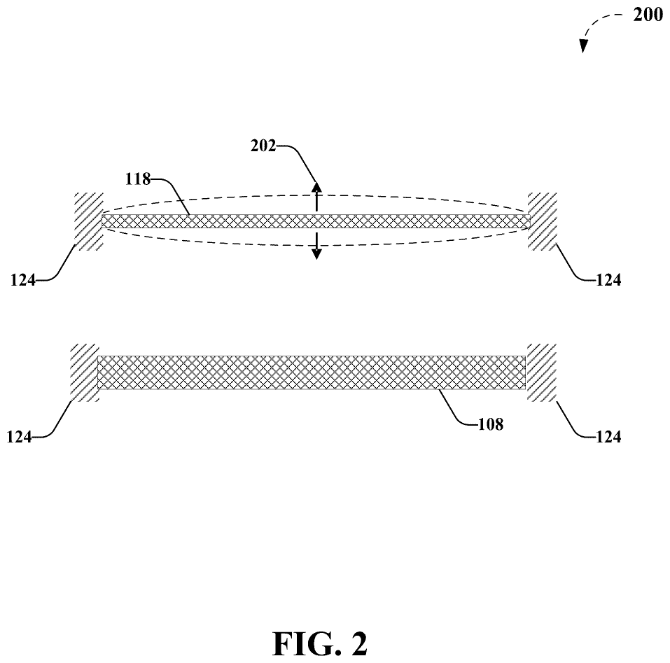

FIG. 2 depicts 200 non-limiting aspects applicable to exemplary MEMS devices or sensors 100 described herein. For instance, as described above, MEMS membrane structures such as transduction membrane 118 are often used as moving members in MEMS devices or sensors to respond to an external input or to create output. Such MEMS membrane structures are anchored at the periphery (e.g., as for the SiN 114 portions 124 of the MEMS devices or sensors 100 at the periphery of the transduction membrane 118) and free to deflect in response to the input away from anchor, near the center. Deformation 202 of the anchored MEMS membrane structure is limited at the anchor, and maximum displacement or deformation 202 occurs at the MEMS membrane structure center, becoming less toward the anchored areas (e.g., portions 124). Thus, MEMS membrane structure areas close to the anchors do not contribute to MEMS device transducer performance, thereby limiting MEMS device performance for a given MEMS die area.

For instance, as a MEMS capacitive sensor, capacitance change of a MEMS membrane structure becomes smaller resulting in a smaller output signal. In response to this limitation of MEMS membrane structure in capacitive sensors, electrode patterning can be used to account for such differences in displacement or deformation 202 in the sensing and non-sensing portions of the MEMS membrane structure to improve SNR. But, despite this potential solution, MEMS die area is still not effectively used. As further described below, other potential solutions to these issues further fail to adequately address these failures to provide MEMS devices employing MEMS membrane structures that efficiently use the MEMS die area, while providing improvements in SNR without suffering from low resonance frequency.

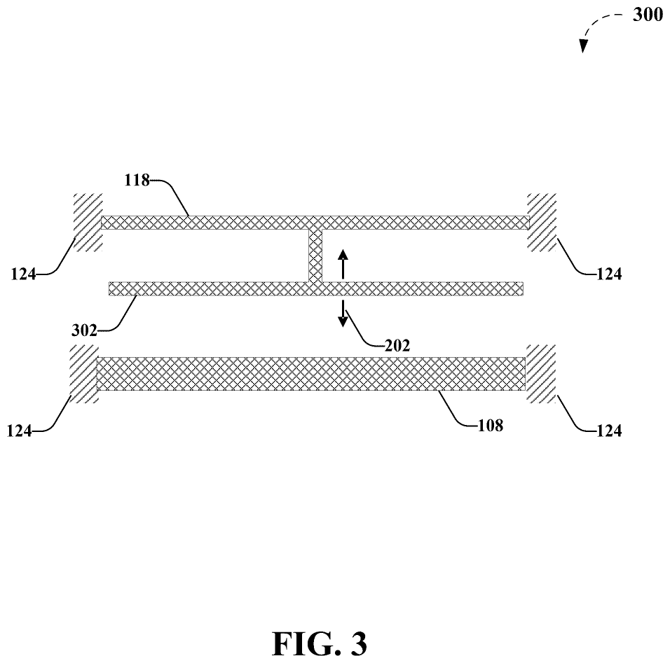

For example, FIG. 3 depicts 300 further non-limiting aspects applicable to exemplary MEMS devices or sensors 100 described herein. One potential solution to such problems of inefficient use of die area is to add a second membrane 302 (such as for a piston motion membrane 116), which, by adding the second membrane 302 to the area of largest displacement or deformation 202 of the transduction membrane 118, would enable the entire MEMS die area to provide a sensing response to displacement or deformation 202 in the transduction membrane 118. However, there remains further problems with such potential solutions.

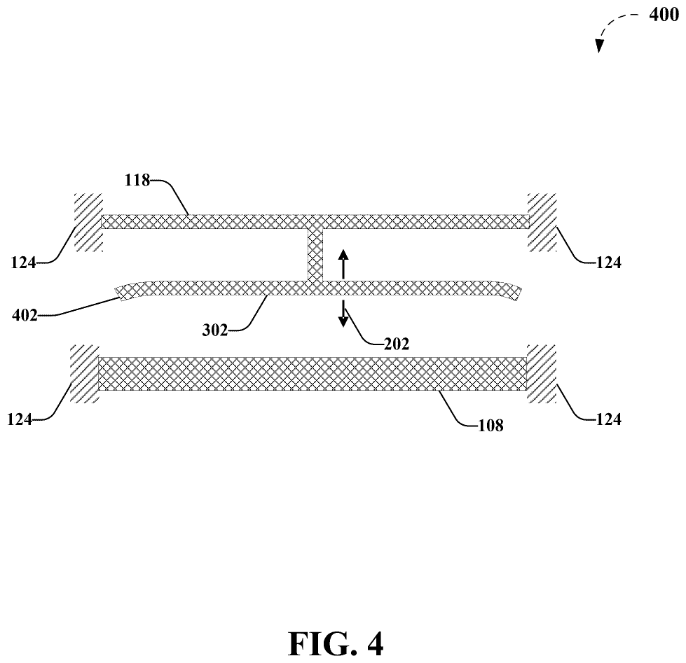

For example, FIG. 4 depicts 400 still further non-limiting aspects applicable to exemplary MEMS devices or sensors 100 described herein. For instance, despite more efficient usage of the entire die area (and potential increased SNR) by extending the second membrane 302 to the extent of the first or transduction membrane 118, it can be expected that such devices would have relatively low resonance frequency due to the larger size of the first or transduction membrane 118. Thus, devices that increase transduction membrane 118 size in an effort to increase sensing output will suffer from lower resonance frequencies. In addition, due to residual film stress and other factors, such as experienced stress gradient, second membrane 302 can be expected to experience warping 402 at the edges of the second membrane 302, which would cause unsatisfactory device performance variation and limited uses for smaller air gap devices. Other solutions that propose extending second membrane 302 outside the area of the transduction membrane 118 or simply repeating an array of transduction membrane 118, second membrane 302 devices offer mixed results.

FIG. 5 provides a simplified cross-section 500 of an exemplary MEMS device or sensor 100 that depicts further non-limiting aspects described herein. For instance, FIG. 5 illustrates the concept of a cell 502 comprising a patterned transduction membrane 118 array of cells that can be configured to deform when exposed to an external input. For instance, an external input can comprise a pressure (e.g., either positive or negative), such as for a pressure sensor, an acoustic pressure (including ultrasonic pressure) such as for an acoustic sensor or microphone, a physical for such as for a force or tactile sensor, and the like. FIG. 5 further illustrates an array of anchor structures 122, wherein each cell of the patterned transduction membrane 118 array can be fixed in position near its periphery relative to a fixed electrode structure 108 via at least one anchor structure 122 of the array of anchor structures 122. In addition, FIG. 5 further illustrates a patterned piston motion membrane 116 array and an array of posts 120, wherein each cell of the patterned transduction membrane 120 array can be mechanically and electrically coupled to a respective cell of the patterned piston motion membrane 116 array via a post 120 of the array of posts 120.

As can be seen in FIG. 1 and FIGS. 7-8 (not shown in FIG. 5), the patterned piston motion membrane 116 array can be configured to translate along the array of anchors 122, and wherein each cell of the patterned piston motion membrane 116 array can be connected to at least one other cell of the patterned piston motion membrane 116 array. Accordingly, disclosed embodiments provide first or patterned transduction membranes 118 array configured to be exposed to an external input and second or patterned piston motion membranes 116 array connected to corresponding first or patterned transduction membranes 118 at their respective locations of largest displacement or deformation 202. In addition, by anchoring the first or patterned transduction membranes 118 via the array of anchors 122, the effective size of the first or patterned transduction membranes 118 array can be predetermined according to the desired MEMS device or sensor 100 resonance frequency, and in any event, it can be expected to be relatively higher than a corresponding device of equivalent die size with only one first or patterned transduction membranes 118.

In addition, disclosed embodiments provide MEMS device or sensor 100 comprising patterned piston motion membranes 116 array where the patterned piston motion membranes 116 are connected to at least one other patterned piston motion membrane 116 of the patterned piston motion membranes 116 array, such that the each other so that the patterned piston motion membranes 116 array can be effectively extended to entire area of first or patterned transduction membranes 118 array (except for some anchor structure 122 of the array of anchor structures 122 and release holes for the embodiments provided in FIGS. 1, 5-19).

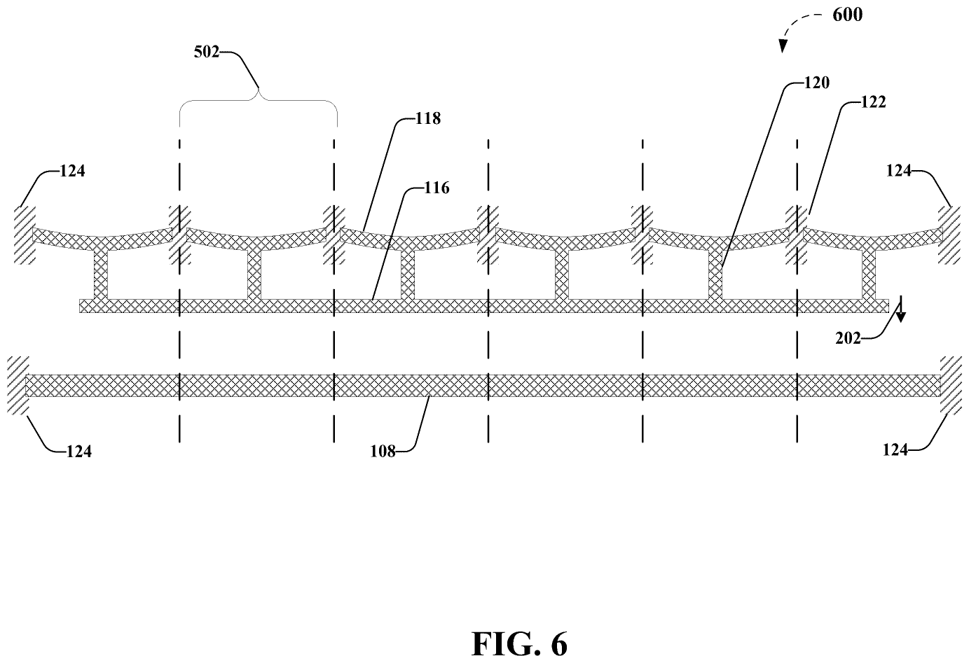

FIG. 6 illustrates 600 particular aspects of non-limiting piston motion membrane 116 structure position under deflection or deformation 202 suitable for use in exemplary MEMS devices or sensors 100 described herein. As such, it can be expected that the entire patterned piston motion membranes 116 array can move in manner parallel to fixed electrode structure 108, thereby enabling piston motion of the patterned piston motion membranes 116 array. That is, FIGS. 5-6 depict the concept of a number of smaller cells 502 each of which comprises a patterned transduction membrane 118 of the patterned transduction membranes 118 array, a patterned piston motion membrane 116 of the patterned piston motion membranes 116 array, a post 120 of the array of posts 120 connecting the two structures, and depending on the embodiment, comprises portions of anchors 122 of the array of the anchors 122 along which the patterned piston motion membrane 116 of the patterned piston motion membranes 116 array translates, where each patterned piston motion membrane 116 of the patterned piston motion membranes 116 array is mechanically and electrically connected to at least one other patterned piston motion membrane 116 of the patterned piston motion membranes 116 array to ensure that the entire patterned piston motion membranes 116 array moves in a piston motion relative to the fixed electrode structure 108.

Thus, FIG. 6 depicts an external input such as a positive pressure applied atop cells 502 of the patterned transduction membranes 118 array, which undergoes deflection or deformation 202, which deflection or deformation 202 is respectively transmitted via posts 120 of the array of posts 120 at the location of maximum deflection or deformation 202 to the corresponding patterned piston motion membrane 116 of the patterned piston motion membranes 116 array, the whole of which, being interconnected, moves in a piston motion.

FIG. 7 provides a top view 700 of an exemplary MEMS device or sensor 100 that depicts further non-limiting aspects described herein. In the top view 700, FIG. 7 omits patterned transduction membranes 118 array and fixed electrode structure 108, among other structures of FIG. 1, to show the patterned piston motion membranes 116 array is mechanically and electrically connected to at least one other patterned piston motion membrane 116 of the patterned piston motion membranes 116 array and the array of posts 120 as well as exemplary relative structure of the array of the anchors 122 along which the patterned piston motion membrane 116 of the patterned piston motion membranes 116 array translates freely. In addition, FIG. 7 provides inset 702 which is shown in FIG. 8 along inset 134 of FIG. 1, to further understand the various interrelated structures.

FIG. 8 depicts 800 still further non-limiting aspects applicable to exemplary MEMS devices or sensors 100 described herein. For instance, inset 702 of FIG. 7 is shown along inset 134 of FIG. 1, to further understand the various interrelated structures. As an example, it can be seen in FIG. 8 more closely how each of the patterned piston motion membranes 116 array is mechanically and electrically connected to at least one other patterned piston motion membrane 116 of the patterned piston motion membranes 116 array and the array of posts 120 as well as exemplary relative structure of the array of the anchors 122 along which the patterned piston motion membrane 116 of the patterned piston motion membranes 116 array translates freely to enable piston motion, high SNR, high resonance frequency MEMS sensors or devices 100.

Thus, FIGS. 7-8 depict a 5×5 array of square cells 502 with the corresponding structures providing piston motion across the entire patterned piston motion membranes 116 array, high SNR, high resonance frequency MEMS sensors or devices 100, while stress warping of the patterned piston motion membrane 116 due to stress gradients could be minimized or eliminated as a result of the cells 502 being interconnected and thereby constrained by at least one other neighboring cell 502, and while reducing the complexity of the fixed electrode structure 108 layout. In addition, the disclosed embodiments have patterned piston motion membrane 116 at same electrical potential of patterned transduction membrane 118, thus eliminating need for sense/parasitic separation while providing unlimited scalability of the cell 502 structure based on design SNR requirements. In addition, the cavity pressure of disclosed MEMS sensors or devices 100 can be designed according to particular application requirements.

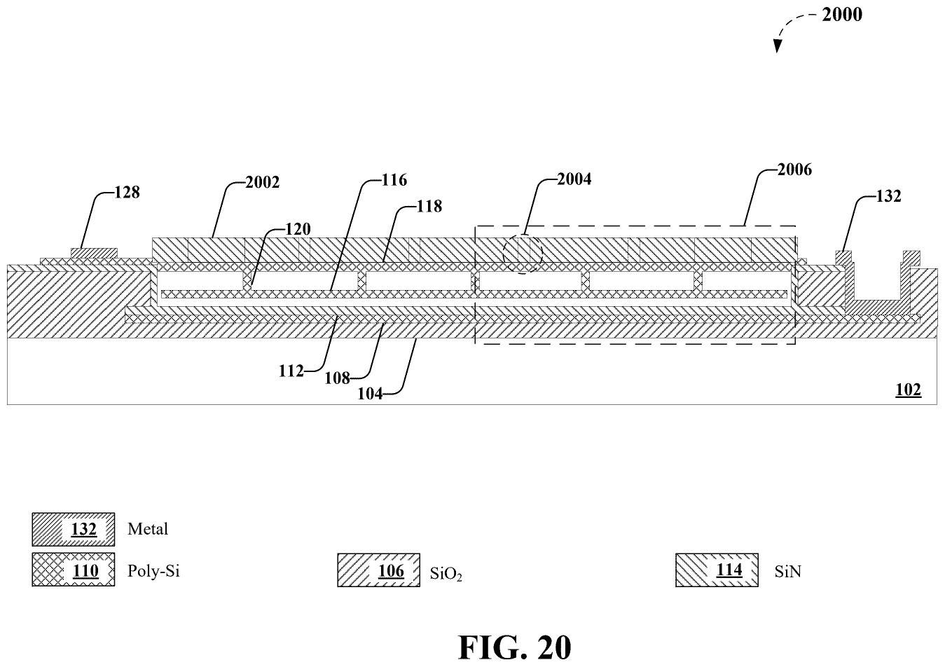

It can be understood that while the various embodiments disclosed in FIGS. 1 and 5-19 are directed an array of square cells 502, the descriptions herein of the various devices is intended to provide understanding of the appended claims without limitation. As such, it can be further understood that there may be suitable substitutions or alternative materials, structures, configurations, and/or processes to accomplish the described techniques, devices, structures, processes, and so on. As non-limiting examples, the numbers of cells 502, arrangements of cells 502 (e.g., hexagonal, square, rectangular), shapes of cells 502 (e.g., hexagonal, square, rectangular), the compliance of patterned transduction membranes 118 array for cells 502, number of etch release structures in the patterned transduction membrane 118, and so on can vary, without limitation. As non-limiting examples, FIGS. 20-23 provide variations directed to a cell stiffener on the patterned transduction membranes 118 array in lieu of anchors 122 within the cavity or space between the patterned transduction membranes 118 array and the patterned piston motion membranes 116 array, hexagonal cells and arrays, and so on.

Accordingly, exemplary MEMS devices or sensors 100 can comprise a patterned transduction membrane 118 array that can be configured to deform when exposed to an external input. For instance, an external input can comprise a pressure (e.g., either positive or negative), such as for a pressure sensor, an acoustic pressure (including ultrasonic pressure) such as for an acoustic sensor or microphone, a physical for such as for a force or tactile sensor, and the like, as further described herein, regarding FIGS. 1 and 5-8. E

Exemplary MEMS devices or sensors 100 can further comprise an array of anchor structures 122, wherein each cell of the patterned transduction membrane 118 array can be fixed in position near its periphery relative to a fixed electrode structure 108 via at least one anchor structure 122 of the array of anchor structures 122.

In addition, exemplary MEMS devices or sensors 100 can comprise a patterned piston motion membrane 116 array, as further described herein. Other embodiments of exemplary MEMS devices or sensors 100 can comprise an array of posts 120, wherein each cell of the patterned transduction membrane 118 array can be mechanically and electrically coupled to a respective cell of the patterned piston motion membrane 116 array via a post 120 of the array of posts 120. For instance, the patterned piston motion membrane 116 array can be configured to translate along the array of anchors 122. In another non-limiting aspect, each cell of the patterned piston motion membrane 116 array can be connected to at least one other cell of the patterned piston motion membrane 116 array, as further described herein, regarding FIGS. 1 and 5-8, for example.

In yet another non-limiting aspect, post 120 of the array of posts 120 can be positioned on each cell of the transduction membrane 118 array at a location configured to deflect or deform 202 with maximum displacement when exposed to the external input. In still other non-limiting aspects, the patterned piston motion membrane 116 array can extend laterally at least to an approximate lateral extent of the patterned transduction membrane 118 array or beyond the approximate lateral extent of the patterned transduction membrane 118 array, as further described herein. In other non-limiting embodiments of MEMS devices or sensors 100, the patterned transduction membrane 118 array and the patterned piston motion membrane 116 array can be arranged in a hexagonal, a square, or a rectangular configuration, as further described herein, regarding FIGS. 1 and 5-8, for example. According to further non-limiting aspects, at least one cell of the transduction membrane 118 array can be configured with different compliance when exposed to the external input relative to at least one other cell of the transduction membrane 118 array when similarly exposed to the external input.

In addition, exemplary MEMS devices or sensors 100 can comprise a set of electrical contacts (e.g., transduction membrane 118 contact pad 128 and fixed electrode structure 108 contact pad 130) for the patterned transduction membrane 118 array and the fixed electrode structure 108. In yet another non-limiting aspect, exemplary MEMS devices or sensors 100 can comprise a MEMS pressure sensor, a MEMS acoustic sensor, or a MEMS tactile sensor, as further described herein.

In other non-limiting embodiments, exemplary MEMS devices or sensors 100 can be configured with a predetermined number of units comprising one cell of the patterned transduction membrane 118 array and the respective cell of the patterned piston motion membrane 116 array based at least in part on a predetermined SNR of the MEMS devices or sensors 100. In still other non-limiting embodiments, an exemplary MEMS device or sensor 100 can have each cell of the transduction membrane 118 array mechanically connected near its periphery to the fixed electrode structure 108 via respective anchor structures 122 of the array of anchor structures 122, as further described herein regarding FIGS. 1 and 5-8. According to still other non-limiting embodiments, an exemplary MEMS device or sensor 100 can have each cell of the transduction membrane 118 array mechanically connected near its periphery to a portion of a package comprising the MEMS device or sensor 100 via at least one anchor structure 122 of the array of anchor structures 122.

FIGS. 9-19 illustrate example, non-limiting, cross-sectional views of exemplary MEMS devices or sensors 100 undergoing fabrication processes in accordance with one or more embodiments described herein.

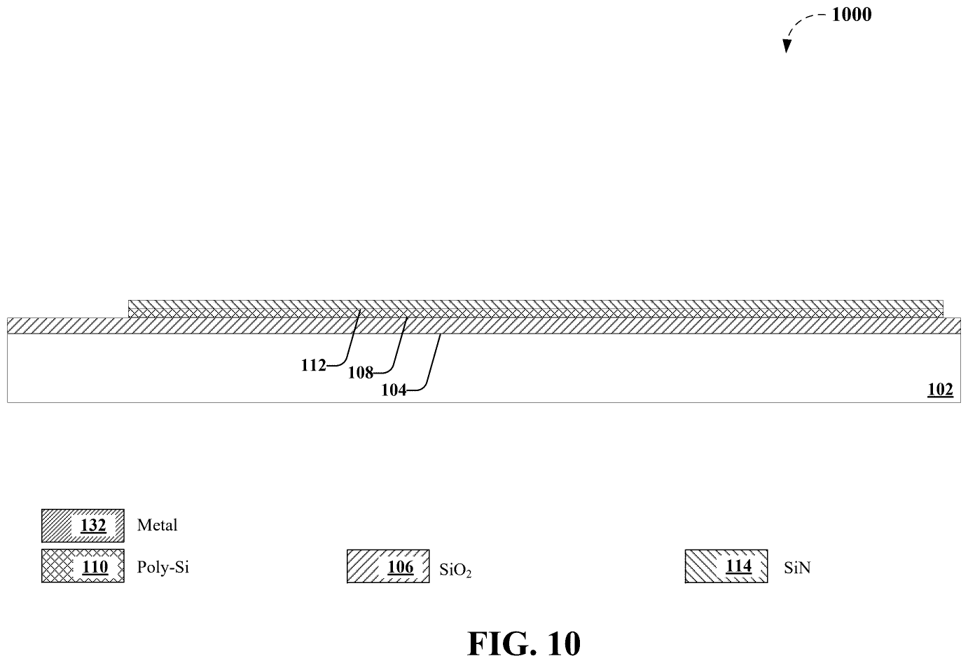

For instance, FIG. 9 depicts 900 exemplary MEMS device or sensor 100 undergoing fabrication processes in which an exemplary device substrate 102 (e.g., a wafer substrate, a silicon wafer) receives a device insulating layer 104 comprising a layer of deposited and/or patterned SiO₂ 106, as further described herein, regarding FIG. 1, for example. In a further non-limiting example, FIG. 10 depicts 1000 exemplary MEMS device or sensor 100 undergoing fabrication processes in which a fixed electrode structure 108 comprising a layer of deposited and/or patterned poly-Si 110 and a passivation layer 112 comprising a layer of deposited and/or patterned SiN 114 can be deposited on top of the fixed electrode structure 108, as further described herein, regarding FIG. 1, for example.

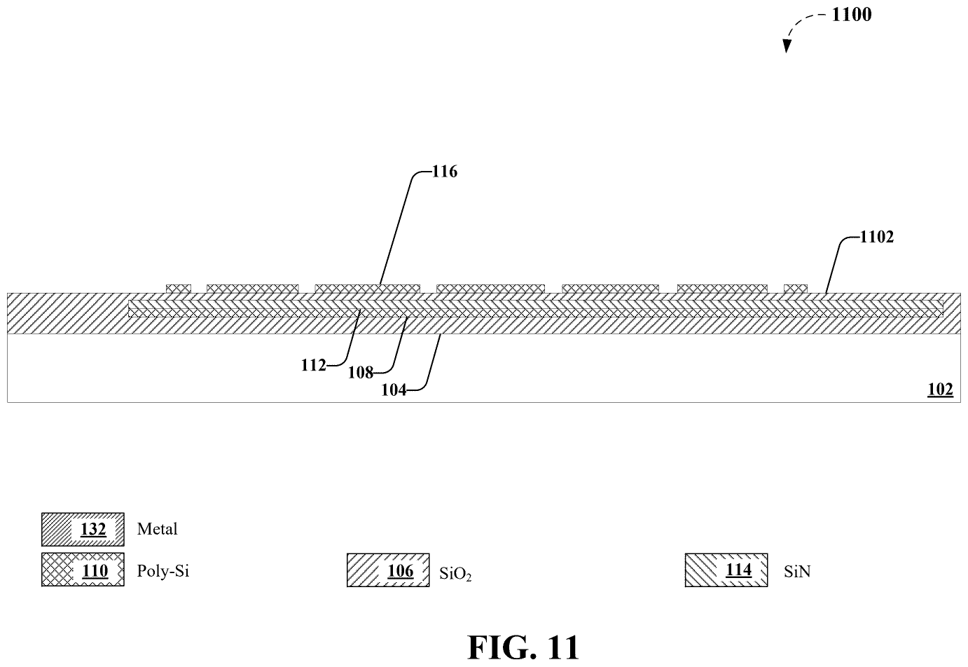

In another non-limiting example, FIG. 11 depicts 1100 exemplary MEMS devices or sensors 100 undergoing fabrication processes in which a layer of deposited and/or patterned SiO₂ 106, is developed as a sacrificial layer 1102 under the prospective piston motion membrane 116 structure. Exemplary MEMS devices or sensors 100 can then undergo a chemical-mechanical polishing process (CMP), and an additional layer of deposited and/or patterned SiO₂ 106 before a layer of deposited and/or patterned poly-Si 110 is added to develop the patterned piston motion membrane 116 array, as further described herein, regarding FIG. 1, for example.

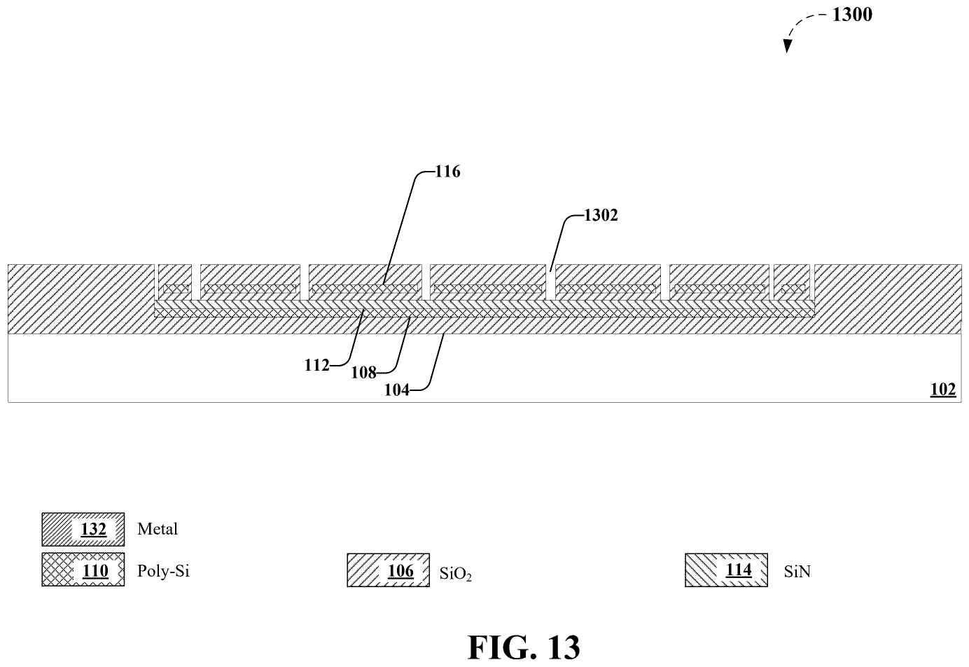

In addition, FIG. 12 depicts 1200 exemplary MEMS device or sensor 100 undergoing fabrication processes in which another layer of deposited and/or patterned SiO₂ 106, is developed as a sacrificial layer 1202 over the patterned piston motion membrane 116 array. Exemplary MEMS devices or sensors 100 can then undergo a chemical-mechanical polishing process CMP, and an additional layer of deposited and/or patterned SiO₂ 106 can be added to develop the array of anchor structures 122, as further described herein, regarding FIG. 1, for example. FIG. 13 depicts 1300 exemplary MEMS device or sensor 100 undergoing fabrication processes in which sacrificial layers 1102 and 1202 can be etched to establish locations 1302 for the fabrication of an array of anchor structures 122, for example, as further described herein, regarding FIG. 1.

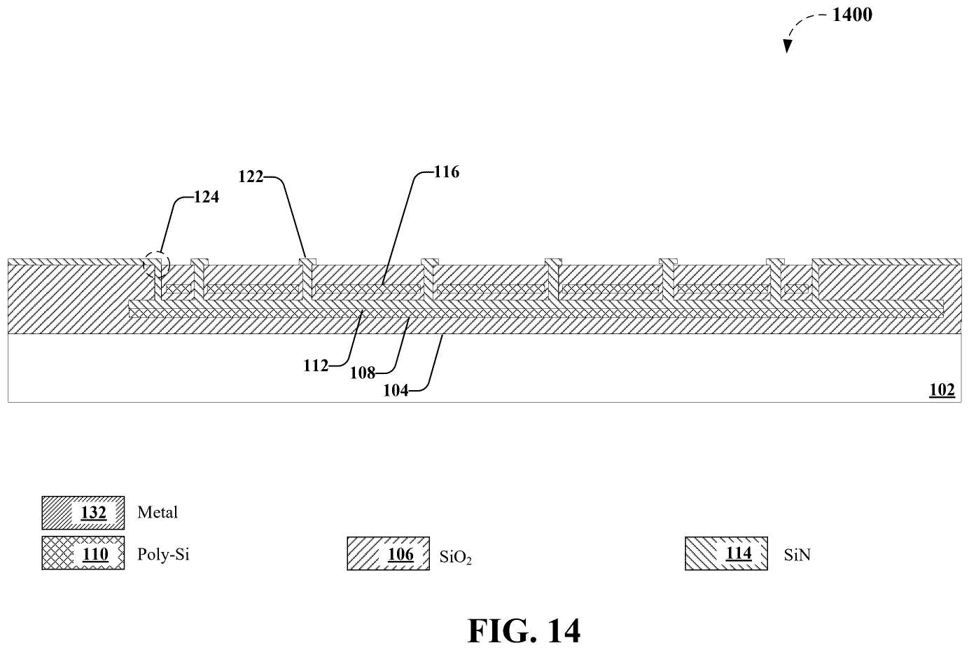

FIG. 14 depicts 1400 exemplary MEMS device or sensor 100 undergoing fabrication processes in which a set of anchor structures 122, arranged in an array, can be deposited on top of the passivation layer 112 in the locations 1302. As a non-limiting example, exemplary anchor structures 122 can comprise one or more layers of deposited and/or patterned SiN 114, for example, as further described herein, regarding FIG. 1. Together with the SiN 114 portions 124 of the MEMS devices or sensors 100 at the periphery of the prospective transduction membrane 118, the set of anchor structures 122 can define cells of the prospective patterned transduction membrane 118 array, to which respective cells of the patterned piston motion membrane 116 array are to be connected via prospective, respective posts 120 of the array of posts 120, as further described herein, regarding FIG. 1.

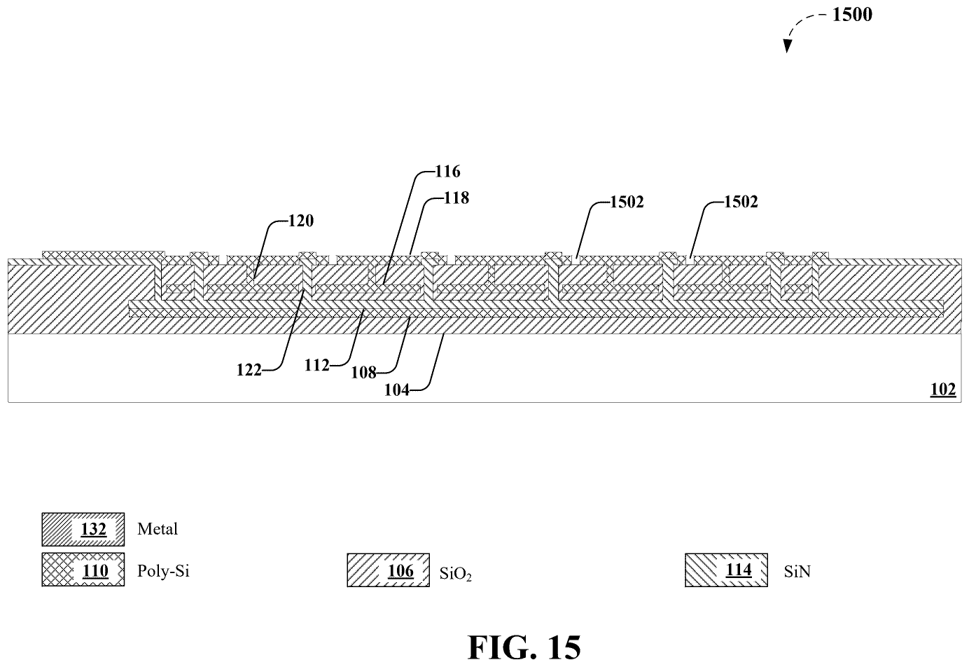

In a further non-limiting example, FIG. 15 depicts 1500 exemplary MEMS device or sensor 100 having undergone fabrication processes in which sacrificial layer 1202 was again etched to establish locations for the fabrication of an array of posts 120, for example, as further described herein, regarding FIG. 1. In addition, FIG. 15 further depicts 1500 exemplary MEMS device or sensor 100 undergoing fabrication processes in which a transduction membrane 118 deposited and/or patterned in an array of transduction membrane 118 structures comprising one or more depositions of poly-Si 110 atop sacrificial layer 1202, and which cells of the patterned transduction membrane 118 array are mechanically and electrically coupled to the patterned piston motion membrane 116 array via an array of posts 120 comprising the one or more depositions of poly-Si 110 and disposed between the transduction membrane 118 and the patterned piston motion membrane 116, for example, as further described herein regarding FIG. 1.

As further depicted 1500 in FIG. 15, a set of etch release structures 1502 can be defined and/or patterned in transduction membrane 118 and configured to enable a uniform wet etch of the sacrificial layers 1102 and 1202 in the area or cavity of the exemplary MEMS devices or sensors 100 between the transduction membrane 118 and the piston motion membrane 116 and freeing the piston motion membrane 116 from the set of anchor structures 122, thus allowing piston motion of the piston motion membrane 116 free of the set of anchor structures 122. As further described herein, the set of etch release structures 1502 can comprise a set of passages through the transduction membrane 118 that are configured to allow the wet etch into the area or cavity and can be configured to reduce etch time required to equalize an etch in the area or cavity. In still further non-limiting aspects of exemplary MEMS devices or sensors 100, the number, position, and arrangement of the set of passages of the set of etch release structures 1502 in the transduction membrane 118 can vary (e.g., in size, number, location), without limitation, as further described herein regarding FIG. 1.

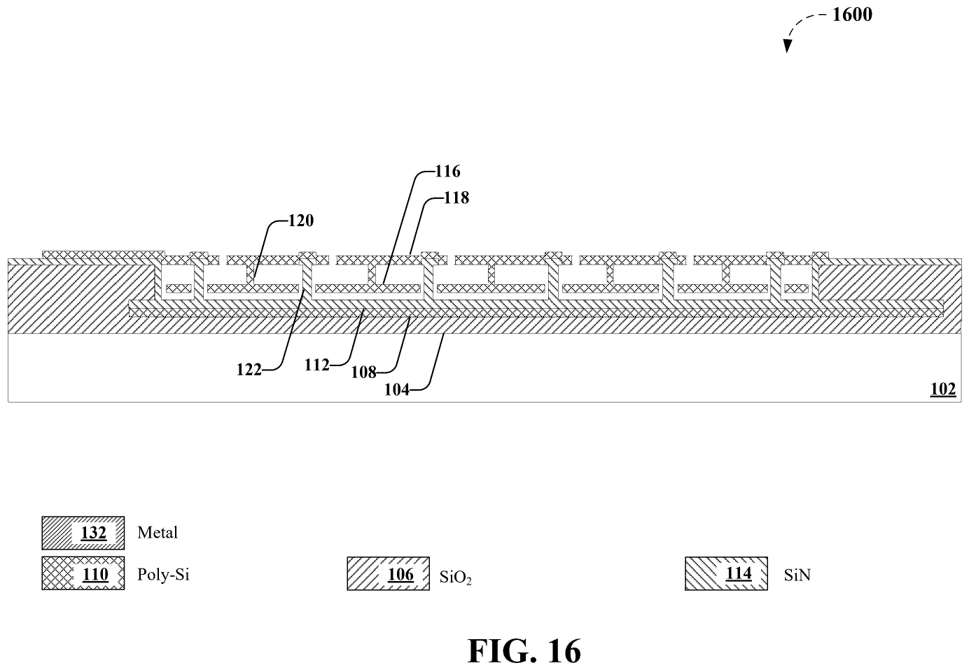

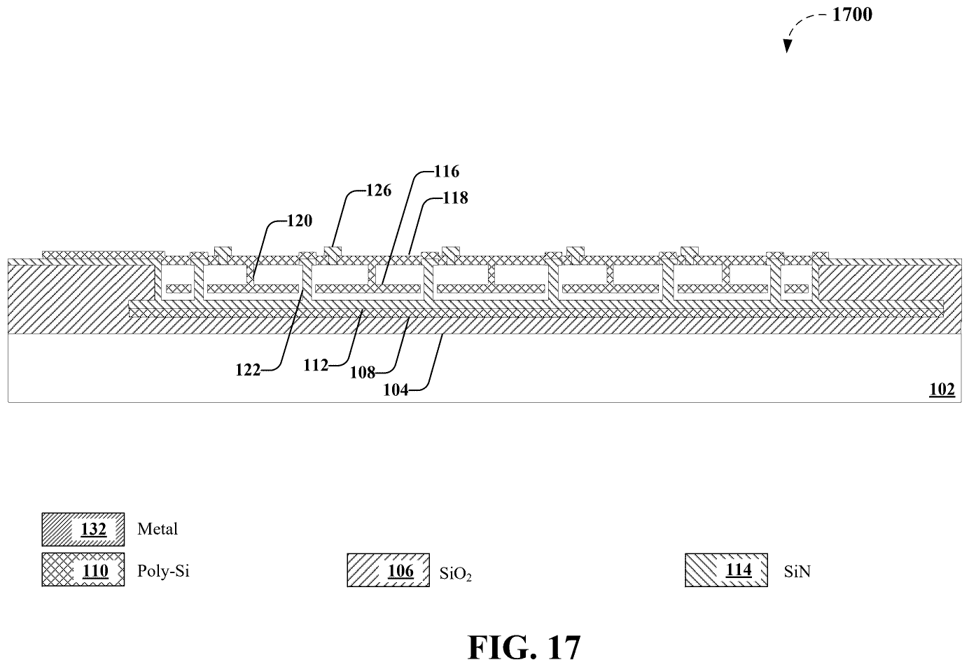

In addition, FIG. 16 depicts 1600 exemplary MEMS device or sensor 100 undergoing fabrication processes in which a uniform membrane release wet etch of the sacrificial layers 1102 and 1202 in the area or cavity of the exemplary MEMS devices or sensors 100 between the transduction membrane 118 and the piston motion membrane 116 and frees the piston motion membrane 116 from the set of anchor structures 122, thus allowing piston motion of the piston motion membrane 116 free of the set of anchor structures 122, as further described herein, regarding FIG. 1, for example. In another non-limiting example, FIG. 17 depicts 1700 exemplary MEMS device or sensor 100 undergoing fabrication processes in which pressure of the cavity between the transduction membrane 118 and the piston motion membrane 116 can be established and a set of etch release hole sealing structures 126 comprising one or more layers of deposited and/or patterned SiN 114 can be deposited, thus sealing the cavity, as further described herein, regarding FIG. 1.

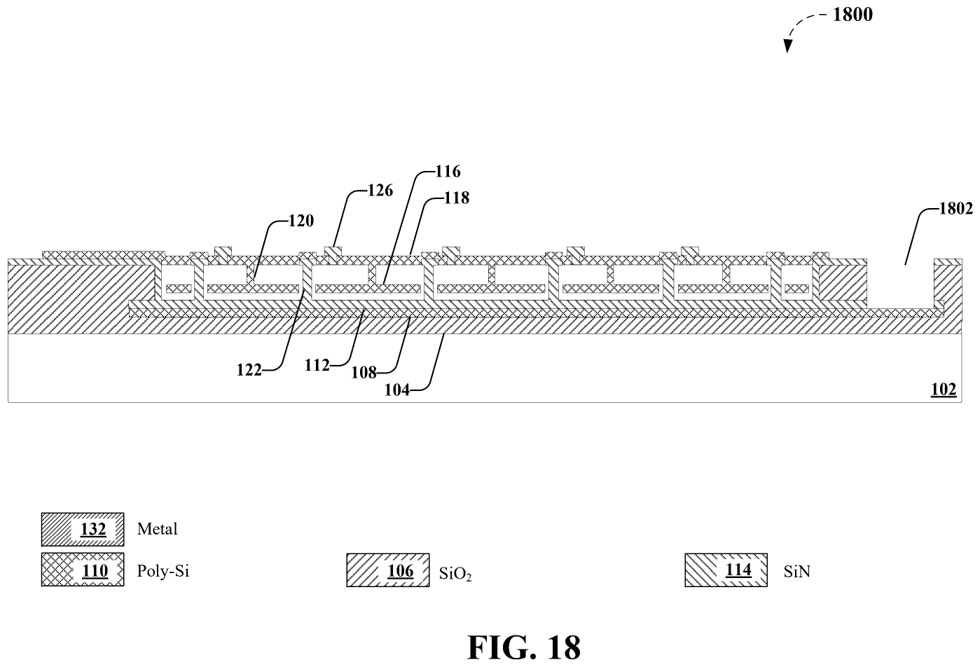

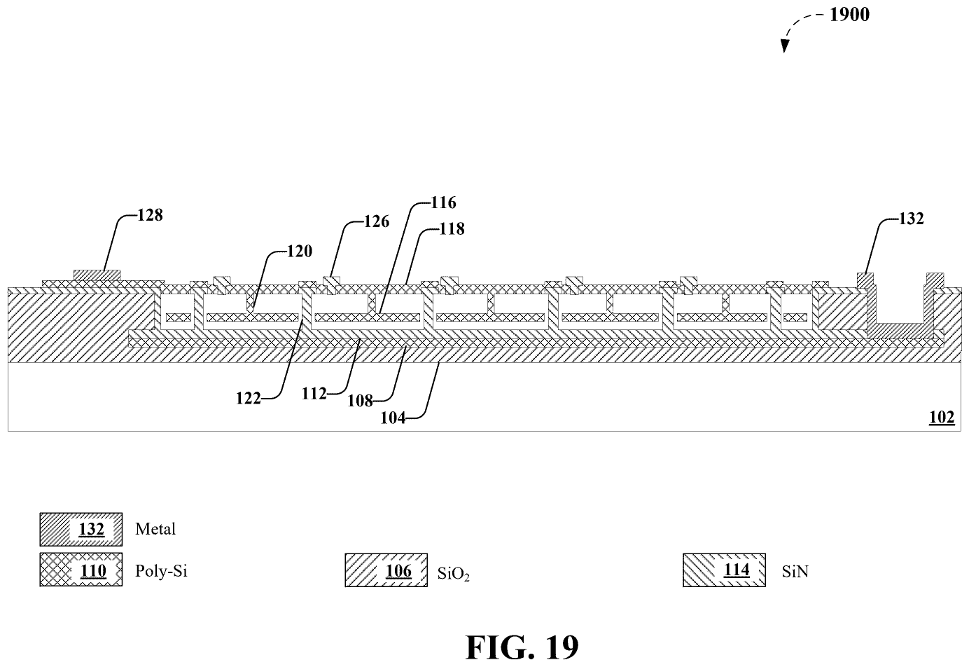

In a further non-limiting example, FIG. 18 depicts 1800 exemplary MEMS device or sensor 100 undergoing fabrication processes in which a contact area 1802 for the fixed electrode structure 108 can be patterned and etched, as further described herein, regarding FIG. 1, for example. FIG. 19 depicts 1900 exemplary MEMS device or sensor 100 undergoing fabrication processes in which one or more layers of deposited and/or patterned metal 132 can form transduction membrane 118 contact pad 128 and fixed electrode structure 108 contact pad 130, as further described herein, regarding FIG. 1.

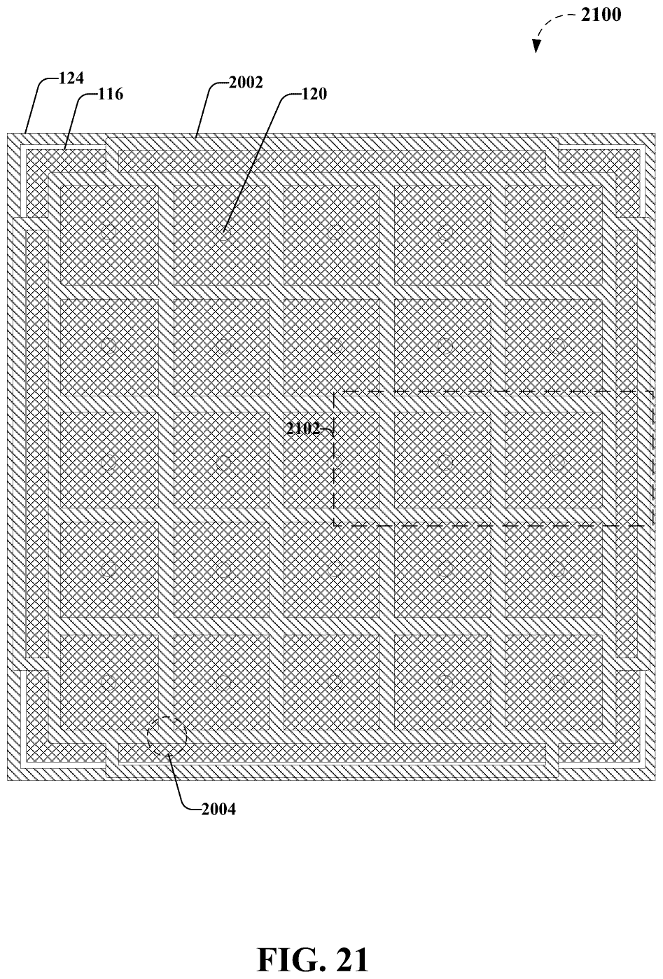

FIG. 20 provides yet another cross-section of an exemplary MEMS device or sensor 2000 that depicts further non-limiting aspects described herein. FIG. 20 MEMS device or sensor 2000 employs similar reference characters for similar features as further described herein regarding FIGS. 1 and 5-19, for example. For instance, whereas FIGS. 1 and 5-19 depict and describe embodiments, wherein an array of anchors 122 located between the patterned transduction membrane 118 array and the fixed electrode structure 108 help define and create a number of smaller cells 502 of the patterned transduction membrane 118 array and the respective cells of the patterned piston motion membrane 116 array, FIG. 20 depicts another embodiment employing a rigid mechanical cell stiffener 2002, with analogous anchor portions 2004 that help define and create a number of smaller cells of the patterned transduction membrane 118 array of FIG. 20. As can be seen in FIG. 21, for example, these anchor portions 2004 can be understood to extend across the entirety of the patterned transduction membrane 118 array, via the rigid mechanical cell stiffener 2002, with the rigid mechanical cell stiffener 2002 being mechanically connected near the periphery of the patterned transduction membrane 118 array and/or to a portion of a package (not shown) comprising the MEMS device or sensor 100 via at least one anchor portion 2004 of the array of anchor portions 2004. Note that in FIG. 20, the etch release structures and etch release hole sealing structures 126 are not shown for clarity. However, it should be understood that the patterned piston motion membrane 116 array could also be formed via membrane release etch as further described herein.

FIG. 21 provides a top view 2100 of an exemplary MEMS device or sensor 2000 that depicts further non-limiting aspects described herein directed to the rigid mechanical cell stiffener 2002, in a square configuration, and mechanically connected near the periphery of the patterned transduction membrane 118 array and/or to a portion of a package (not shown) comprising the MEMS device or sensor 100 via at least one anchor portion 2004 of the array of anchor portions 2004. Thus, the provided rigid mechanical cell stiffener 2002 can provide the functional equivalent of the array of anchor structures 122 as described herein except from the top side of the patterned transduction membrane 118 array, which can avoid the necessity of anchors connected to the passivation layer 112 over the fixed electrode structure 108, thus, freeing the patterned piston motion membrane 116 array from the necessity of translating along the array of anchor structures 122 as described herein, can reduce air damping in the cavity between the patterned transduction membrane 118 array and the fixed electrode structure 108, and so on.

In one embodiment, the rigid mechanical cell stiffener 2002 can be formed atop the patterned transduction membrane 118 array as described. However, in other non-limiting embodiments, wafer bonding can be used to seal the cavity between a wafer comprising the fixed electrode structure 108 closed chamber, for example, and another wafter comprising the rigid mechanical cell stiffener 2002, the patterned transduction membrane 118 array, and the patterned piston motion membrane 116 array, instead of employing a membrane release etch and sealing process as further described herein. In addition, FIG. 20 depicts inset 2006, which, in conjunction with inset 2102 in FIG. 21, further illustrates non-limiting aspects of the MEMS devices or sensors 100 regarding anchor portions 2004, the patterned piston motion membrane 116 array, and the arrangement of the respective cells of patterned piston motion membrane 116 array in a square configuration.

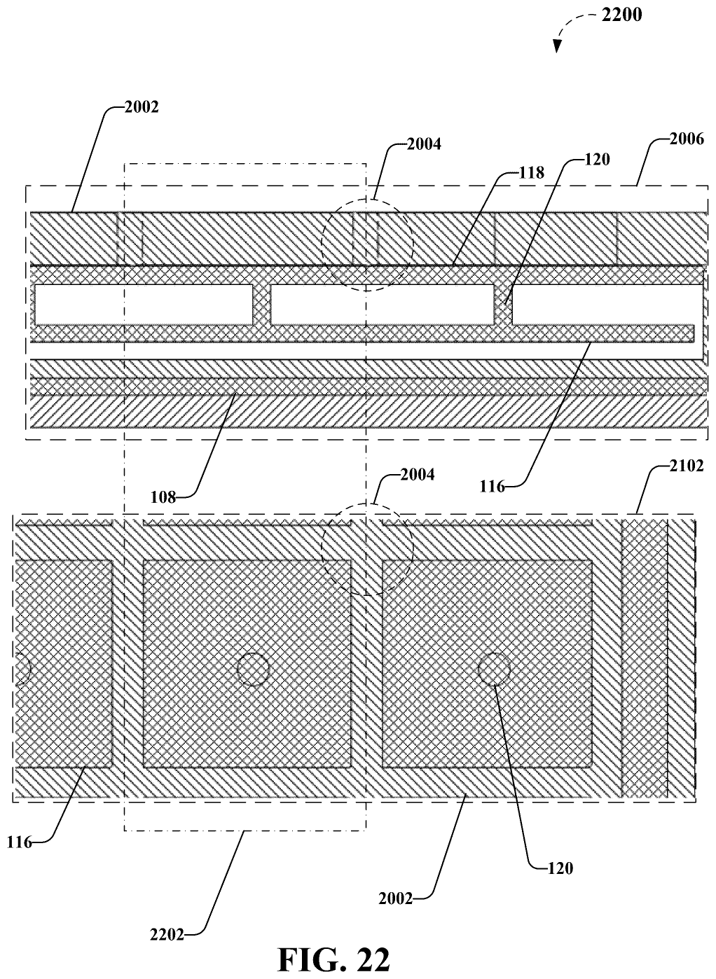

FIG. 22 depicts 2200 further non-limiting aspects of exemplary MEMS devices or sensors 2000 described herein including the concept of cells 2202 defined by the rigid mechanical cell stiffener 2002, in a square configuration, and mechanically connected near the periphery of the patterned transduction membrane 118 array (not shown) and/or to a portion of a package (not shown) comprising the MEMS device or sensor 100 via at least one anchor portion 2004 of the array of anchor portions 2004.

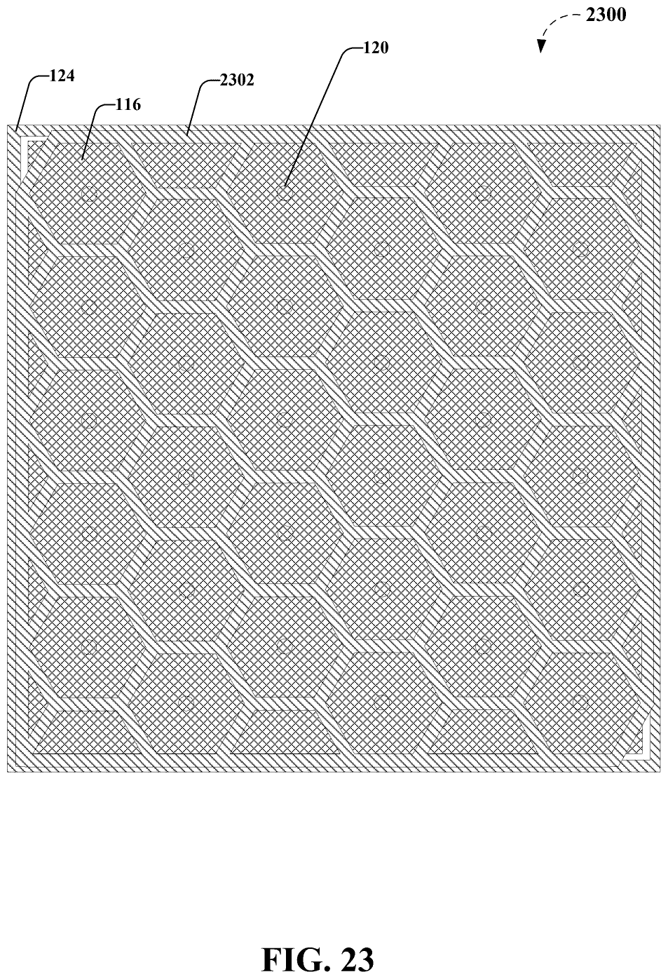

FIG. 23 provides a top view 2300 of another exemplary MEMS device or sensor that depicts further non-limiting aspects described herein, wherein the rigid mechanical cell stiffener 2302, in a hexagonal configuration, defines the hexagonal cells, which are mechanically connected near the periphery of the patterned transduction membrane 118 array (not shown) and/or to a portion of a package (not shown) comprising the MEMS device or sensor 100 via at least one anchor portion 2004 of the array of anchor portions 2004.

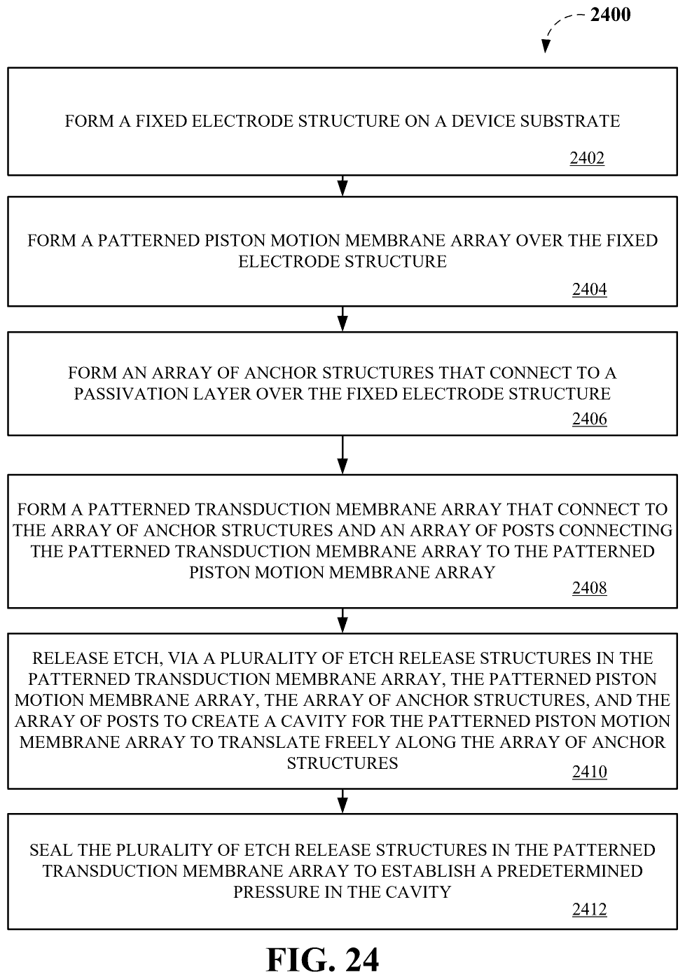

In view of the subject matter described supra, methods that can be implemented in accordance with the subject disclosure will be better appreciated with reference to the flowcharts of FIG. 24. While for purposes of simplicity of explanation, the methods are shown and described as a series of blocks, it is to be understood and appreciated that such illustrations or corresponding descriptions are not limited by the order of the blocks, as some blocks may occur in different orders and/or concurrently with other blocks from what is depicted and described herein. Any non-sequential, or branched, flow illustrated via a flowchart should be understood to indicate that various other branches, flow paths, and orders of the blocks, can be implemented which achieve the same or a similar result. Moreover, not all illustrated blocks may be required to implement the methods described hereinafter.

### Exemplary Methods

FIG. 24 provides a non-limiting flow diagram of exemplary methods 2400 according to various non-limiting aspects as described herein. For instance, at 2402, exemplary methods 2400 of fabricating a MEMS sensors or devices 100 can comprise forming a fixed electrode structure (e.g., fixed electrode structure 108) on a device substrate (e.g., device substrate 102), as further described herein, for example, regarding FIGS. 1 and 5-19. For instance, as described herein, regarding FIG. 9, for example, SiO₂ 106 can be deposited on a device wafer (e.g., comprising Si substrate 102) to create device insulating layer 104. As further described herein, regarding FIG. 10, for example, a doped poly-Si 110 layer can be deposited to create a fixed electrode structure 108 over device insulating layer 104 SiO₂ 106 and a SiN 114 passivation layer 112 can be deposited over the fixed electrode structure 108 doped poly-Si 110, which poly-Si 110/SiN 114 can be patterned to establish fixed electrode structure 108. In another non-limiting aspect, regarding FIG. 11, for example, SiO₂ 106 can be deposited over fixed electrode structure 108, the MEMS sensors or devices 100 undergoing fabrication can receive CMP and SiO₂ 106 can be further deposited to create sacrificial layer 1102.

Exemplary methods 2400 can further comprise, at 2404, forming a patterned piston motion membrane array (e.g., patterned piston motion membrane 116 array) over the fixed electrode structure (e.g., fixed electrode structure 108). In a further non-limiting aspect, exemplary methods 2400 can further comprise, at 2404, depositing doped poly-Si 110 for patterned piston motion membrane 116 array, for example, as further described herein regarding FIG. 11. In another non-limiting aspect, regarding FIG. 11, for example, poly-Si 110 can be patterned to establish a patterned piston motion membrane 116 array, wherein each cell of the patterned piston motion membrane 116 array is connected to at least one other cell of the patterned piston motion membrane 116 array. In addition, as further described herein regarding FIG. 12, for example, SiO₂ 106 can be deposited over patterned piston motion membrane 116 array to create sacrificial layer 1202 and the MEMS sensors or devices 100 undergoing fabrication can receive CMP.

In further non-limiting embodiments, exemplary methods 2400 can comprise, at 2406, forming an array of anchor structures (e.g., array of anchor structures 122) that connect to a passivation layer (e.g., passivation layer 112) over the fixed electrode structure (e.g., fixed electrode structure 108), as further described herein, for example, regarding FIGS. 1 and 5-19. In a non-limiting aspect, as further described herein regarding FIG. 12, for example, SiO₂ 106 can be deposited over patterned piston motion membrane 116 array to complete sacrificial layer 1202. In addition, as further described herein regarding FIG. 13, for example, sacrificial layer 1202 SiO₂ 106 can be patterned in an arrangement to establish locations 1302 for an array of anchor structures 122 to be etched to the SiN 114 passivation layer 112 over fixed electrode structure 108. Moreover, SiN 114 for the array of anchor structures 112 can be deposited and patterned to establish the array of anchor structures 122 to the SiN 114 passivation layer 112 over fixed electrode structure 108, as further described herein regarding FIG. 14, for example.

In still further non-limiting embodiments, exemplary methods 2400 can comprise, at 2408, forming a patterned transduction membrane array (e.g., patterned transduction membrane 118 array) that connects to the array of anchor structures (e.g., array of anchor structures 122) and an array of posts (e.g., array of posts 120) connecting the patterned transduction membrane array (e.g., patterned transduction membrane 118 array)to the patterned piston motion membrane array (e.g., patterned piston motion membrane 116 array). In a non-limiting aspect, as further described herein regarding FIG. 15, for example, sacrificial layer 1202 SiO₂ 106 can be patterned in an arrangement to establish locations for an array of posts 120 for the patterned piston motion membrane 116 array, and doped poly-Si 110 can be deposited on the array of anchors 122 to the SiN 114 passivation layer 112 over fixed electrode structure 108 and the array of posts 120 to create the patterned transduction membrane 118 array and connect the patterned piston motion membrane 116 array to the patterned transduction membrane 118 array. In addition, as further described herein regarding FIG. 15, for example, poly-Si 110 of the patterned transduction membrane 118 array can be patterned to establish a patterned transduction membrane 116 array having a plurality of etch release structures 1502, wherein each cell of the patterned transduction membrane 118 array is mechanically and electrically coupled to a respective cell of the patterned piston motion membrane 116 array via a post 120 of the array of posts 120, and wherein each cell of the patterned transduction membrane 118 array is mechanically connected near its periphery to the fixed electrode structure 108 via at least one anchor structure 122 of the array of anchor structures 122.

In other non-limiting embodiments, exemplary methods 2400 can comprise, at 2410, release etching, via a set of etch release structures (e.g., set of etch release structures 1502) in the patterned transduction membrane array, the patterned piston motion membrane array (e.g., patterned piston motion membrane 116 array), the array of anchor structures (e.g., array of anchor structures 122), and the array of posts (e.g., array of posts 120) to create a cavity for the patterned piston motion membrane array (e.g., patterned piston motion membrane 116 array) to translate freely along the array of anchor structures (e.g., array of anchor structures 122), as further described herein, for example, regarding FIGS. 1 and 5-19. For instance, exemplary methods 2400 can comprise, at 2410, membrane release etching of sacrificial layers 1102 and 1202 SiO₂ 106, via the plurality of etch release structures 1502, at least a portion of SiO₂ 106 between at least the fixed electrode structure 108 and the patterned piston motion membrane 116 array, between the patterned piston motion membrane 116 array and the patterned transduction membrane 118 array, and between the patterned piston motion membrane 116 array and the anchor structures 122 of the array of anchor structures 122, thereby releasing the patterned piston motion membrane 116 array from the array of anchor structures 122, for example, as further described herein regarding FIG. 16, for example.

In addition, exemplary methods 2400 can comprise, at 2412, sealing the set of etch release structures (e.g., set of etch release structures 1502) in the patterned transduction membrane array (e.g., patterned transduction membrane 118 array) to establish a predetermined pressure in the cavity. Thus, exemplary methods 2400 can comprise, at 2412, depositing and patterning etch release hole sealing structures 126 SiN 114 to seal the plurality of etch release structures 1502, for example, as further described herein regarding FIG. 17, for example.

Moreover, exemplary methods 2400 can further comprise forming a set of contacts (e.g., transduction membrane 118 contact pad 128 and fixed electrode structure 108 contact pad 130) to the patterned transduction membrane array (e.g., patterned transduction membrane 118 array) and the fixed electrode structure (e.g., fixed electrode structure 108), as further described herein, for example, regarding FIGS. 1 and 5-19. In a non-limiting aspect, exemplary methods 2400 can comprise etching the device wafer passivation layer 112 SiN 114 and sacrificial layers 1102 and 1202 SiO₂ 106 to establish a contact area 1802 to the fixed electrode structure 108 doped poly-Si 110, as further described herein regarding FIG. 18. In addition, exemplary methods 2400 can further comprise depositing and patterning contact metal 132 to form a set of contacts (e.g., transduction membrane 118 contact pad 128 and fixed electrode structure 108 contact pad 130) for the patterned transduction membrane 118 array and the fixed electrode structure 108 doped poly-Si 110.

What has been described above includes examples of the embodiments of the subject disclosure. It is, of course, not possible to describe every conceivable combination of configurations, components, and/or methods for purposes of describing the claimed subject matter, but it is to be appreciated that many further combinations and permutations of the various embodiments are possible. Accordingly, the claimed subject matter is intended to embrace all such alterations, modifications, and variations that fall within the spirit and scope of the appended claims. While specific embodiments and examples are described in subject disclosure illustrative purposes, various modifications are possible that are considered within the scope of such embodiments and examples, as those skilled in the relevant art can recognize. For example, while embodiments of the subject disclosure are described herein in the context of MEMS sensors (e.g., such as MEMS acoustic sensors), it can be appreciated that the subject disclosure is not so limited. For instance, various exemplary implementations may find application in other areas of MEMS sensors, devices, and methods, without departing from the subject matter described herein.

In addition, the words “example” or “exemplary” is used herein to mean serving as an example, instance, or illustration. Any aspect or design described herein as “exemplary” is not necessarily to be construed as preferred or advantageous over other aspects or designs. Rather, use of the word, “exemplary,” is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more”unless specified otherwise or clear from context to be directed to a singular form.

In addition, while an aspect may have been disclosed with respect to only one of several embodiments, such feature may be combined with one or more other features of the other embodiments as may be desired and advantageous for any given or particular application. Furthermore, to the extent that the terms “includes,” “including,” “has,” “contains,” variants thereof, and other similar words are used in either the detailed description or the claims, these terms are intended to be inclusive in a manner similar to the term “comprising” as an open transition word without precluding any additional or other elements.

What is claimed is:

1. A microelectromechanical systems (MEMS) apparatus comprising:
a patterned transduction membrane array that is configured to deform when exposed to an external input;
an array of anchor structures, wherein each cell of the patterned transduction membrane array is fixed in position near its periphery relative to a fixed electrode structure via at least one anchor structure of the array of anchor structures;
a patterned piston motion membrane array; and
an array of posts, wherein each cell of the patterned transduction membrane array is mechanically and electrically coupled to a respective cell of the patterned piston motion membrane array via a post of the array of posts, wherein the patterned piston motion membrane array is configured to translate along the array of anchors, and wherein each cell of the patterned piston motion membrane array is connected to at least one other cell of the patterned piston motion membrane array.

2. The MEMS apparatus of claim 1, wherein the post of the array of posts is positioned on each cell of the transduction membrane array at a location configured to deform with maximum displacement when exposed to the external input.

3. The MEMS apparatus of claim 1, wherein the patterned piston motion membrane array extends laterally at least to an approximate lateral extent of the patterned transduction membrane array or beyond the approximate lateral extent of the patterned transduction membrane array.

4. The MEMS apparatus of claim 1, wherein the patterned transduction membrane array and the patterned piston motion membrane array are arranged in at least one of a hexagonal, a square, or a rectangular configuration.

5. The MEMS apparatus of claim 1, wherein at least one cell of the transduction membrane array is configured with different compliance when exposed to the external input relative to at least one other cell of the transduction membrane array when similarly exposed to the external input.

6. The MEMS apparatus of claim 1, further comprising:
a set of electrical contacts for the patterned transduction membrane array and the fixed electrode structure.

7. The MEMS apparatus of claim 1, comprising at least one of a MEMS pressure sensor, a MEMS acoustic sensor, or a MEMS tactile sensor.

8. The MEMS apparatus of claim 1, wherein the apparatus is configured with a predetermined number of units comprising one cell of the patterned transduction membrane array and the respective cell of the patterned piston motion membrane array based at least in part on a predetermined Signal to Noise Ratio (SNR) of the apparatus.

9. The MEMS apparatus of claim 1, wherein each cell of the transduction membrane array is mechanically connected near its periphery to the fixed electrode structure via respective anchor structures of the array of anchor structures.

10. The MEMS apparatus of claim 1, wherein each cell of the transduction membrane array is mechanically connected near its periphery to a portion of a package comprising the apparatus via the at least one anchor of the array of anchors.

11. A method comprising:
forming a fixed electrode structure on a device substrate;
forming a patterned piston motion membrane array over the fixed electrode structure;
forming an array of anchor structures that connect to a passivation layer over the fixed electrode structure;
forming a patterned transduction membrane array that connects to the array of anchor structures and an array of posts that connects the patterned transduction membrane array to the patterned piston motion membrane array;
release etching, via a plurality of etch release structures in the patterned transduction membrane array, the patterned piston motion membrane array, the array of anchor structures, and the array of posts to create a cavity for the patterned piston motion membrane array to translate freely along the array of anchor structures; and
sealing the plurality of etch release structures in the patterned transduction membrane array to establish a predetermined pressure in the cavity.

12. The method of claim 11, further comprising:
forming a set of contacts to the patterned transduction membrane array and the fixed electrode structure.

13. The method of claim 11, wherein the forming the patterned piston motion membrane array comprises forming the patterned piston motion membrane array wherein each cell of the patterned piston motion membrane array is connected to at least one other cell of the patterned piston motion membrane array.

14. The method of claim 11, wherein the forming the patterned piston motion membrane array comprises forming the patterned piston motion membrane array wherein the patterned piston motion membrane array is configured to translate along the array of anchors.

15. The method of claim 11, wherein the forming the patterned transduction membrane array comprises forming the patterned transduction membrane array wherein each cell of the patterned transduction membrane array is mechanically and electrically coupled to a respective cell of the patterned piston motion membrane array via a post of the array of posts.

16. The method of claim 11, wherein the forming the patterned transduction membrane array comprises forming the patterned transduction membrane array wherein each cell of the patterned transduction membrane array is fixed in position near its periphery relative to the fixed electrode structure via at least one anchor structure of the array of anchor structures.

17. The method of claim 11, wherein the forming the patterned transduction membrane array comprises forming the patterned transduction membrane array wherein each cell of the patterned transduction membrane array is configured to deform when exposed to an external input.

18. The MEMS apparatus of claim 11, wherein the forming the patterned piston motion membrane array comprises forming the patterned piston motion membrane array wherein the patterned piston motion membrane array extends laterally at least to an approximate lateral extent of the patterned transduction membrane array.

19. The MEMS apparatus of claim 18, wherein the forming the patterned piston motion membrane array comprises forming the patterned piston motion membrane array wherein the patterned piston motion membrane array extends beyond the approximate lateral extent of the patterned transduction membrane array.

20. The MEMS apparatus of claim 11, wherein the forming the patterned piston motion membrane array and the forming the patterned transduction membrane array comprises forming the patterned piston motion membrane array and forming the patterned transduction membrane array wherein the patterned piston motion membrane array and the patterned transduction membrane array are arranged in at least one of a hexagonal, a square, or a rectangular configuration.
